(19) United States
(12) Patent Application Publication
(10) Pub. No.: US 2025/0141472 A1
(43) Pub. Date: May 1, 2025

(54) STAIRCASE MATRIX CODE AND HIGHLY PARALLEL LOW-LATENCY ORDERED STATISTICS DECODING METHOD THEREOF

(71) Applicant: SUN YAT-SEN UNIVERSITY, Guangzhou City (CN)

(72) Inventors: Xiao MA, Guangzhou City (CN); Yiwen WANG, Guangzhou City (CN); Jifan LIANG, Guangzhou City (CN); Qianfan WANG, Guangzhou City (CN)

(73) Assignee: SUN YAT-SEN UNIVERSITY, Guangzhou City (CN)

(21) Appl. No.: 18/745,853

(22) Filed: Jun. 17, 2024

(30) Foreign Application Priority Data
Nov. 1, 2023 (CN) 202311434575.X

(51) Int. Cl. H03M 13/11; H03M 13/45

(52) U.S. Cl. CPC H03M 13/118; H03M 13/451

(57) ABSTRACT

Disclosed are a staircase matrix code and a highly parallel low-latency ordered statistics decoding (OSD) method thereof. The staircase matrix code may be divided into a staircase generator matrix code and a staircase parity-check matrix code, and a corresponding generator matrix or parity-check matrix thereof has a staircase structure, or has a staircase structure after row and column permutation. Based on the special staircase structure, special highly parallel low-latency OSD can be employed to decode the staircase matrix code. Specifically, at least one reliable bit is selected from bits corresponding to each staircase to constitute an extended reliable basis, then a corresponding generator matrix or parity-check matrix has an upper triangular or lower triangular structure. Under the special triangular structure, parallel Gaussian elimination of all rows can be implemented, and then re-encoding and the like are executed to complete decoding. The staircase structure proposed in the present disclosure is combined with a special OSD design, thereby solving the deficiency of conventional OSD that Gaussian elimination can only be executed serially, and the staircase structure can be further combined with locally constrained OSD and the like to reduce re-encoding times, thereby implementing low-latency, low-complexity and high-reliability decoding.

### FIELD OF THE INVENTION

The present disclosure belongs to the technical field of digital communications, and in particular, to a staircase matrix code and a highly parallel low-latency ordered statistics decoding (OSD) method thereof.

### BACKGROUND OF THE INVENTION

An OSD algorithm for linear block codes was first proposed by Fossorier and Linshu in 1995. It can be applied to any linear block code and can obtain maximum likelihood decoding algorithm performance without considering complexity. In fact, the OSD algorithm is a typical (approximate) maximum likelihood decoding algorithm. With ultra-reliability and low-latency communication becoming one of the three major application scenarios of 5G, OSD that can provide ultra-reliability performance has attracted extensive attention and discussion in academic and industrial fields.

A basic idea of the OSD is to sort bits according to the reliability of a received sequence, then find a most reliable basis through Gaussian elimination, perform error pattern search on the most reliable basis to obtain a candidate codeword list by re-encoding, and finally select by related measures an optimal codeword to output to complete decoding. The OSD has many advantages, but it requires the Gaussian elimination to be executed on each set of received sequences according to their reliability. However, Gaussian elimination of existing OSD can only be implemented serially, which leads to an inevitable decoding latency, and severely limits practical applications of the OSD algorithm. Furthermore, the test order of error patterns in a conventional OSD algorithm is implemented based on Hamming weight, and soft information of the most reliable basis in actual reception is not considered, which needs to be further optimized and promoted.

### SUMMARY OF THE INVENTION

A main object of the present disclosure is to overcome the shortcomings and deficiencies of the prior art, and aiming at the serial Gaussian elimination problem of OSD, a staircase matrix code and a highly parallel low-latency OSD method thereof are proposed, where a permutation matrix in the form of an upper triangle or a lower triangle is obtained by a special staircase-form generator matrix or parity-check matrix, so that fully parallel Gaussian elimination can be implemented, and novel OSD, such as locally constrained OSD, can be combined, thereby greatly reducing re-encoding times, and implementing low-complexity, low-latency, and high-performance decoding.

In order to achieve the above object, the present disclosure employs the following technical solution:

the present disclosure discloses a staircase matrix code and a highly parallel low-latency OSD method thereof, where a staircase matrix is described as: the [symbol] row of the staircase matrix is defined as [symbol] =( [symbol] , [symbol] , [symbol] ), where [symbol] is a binary sequence with a length of Σ_{0≤m<l}wₘ, [symbol] is an all-I sequence with a length of [symbol] ≥1, and [symbol] is an all-zero sequence with a length of n− [symbol] wₘ; the staircase matrix code is divided into a staircase generator matrix code and a staircase parity-check matrix code from a definition perspective, where a generator matrix of the staircase generator matrix code has a staircase structure or has a staircase structure after row and column permutation, k groups of w=(w₀, w₁, . . . , wₖ₋₁) constitute a profile of the staircase generator matrix, and wᵢ≥1, Σwᵢ=n; a parity-check matrix of the staircase parity-check matrix code has a staircase structure or has a staircase structure after row and column permutation, n−k groups of w=(w₀, w₁, . . . , wₙ₋ₖ₋₁) constitute a profile of the staircase parity-check matrix, and wᵢ≥1, Σwᵢ=n; and an information sequence u ∈ [symbol] and a staircase matrix code [symbol] [n, k] are given, a specific coding and decoding process of the staircase matrix code and the highly parallel low-latency OSD method thereof includes:

(1) a codeword c of the staircase generator matrix code is in a row generator space of a staircase generator matrix G_{k×n}, namely, c ∈ {uG_{k×n}|u ∈ [symbol] ₂}; and a codeword c of the staircase parity-check matrix code is in a null space of a staircase parity-check matrix H_{(n-k)×n}, namely, the codeword c satisfying H_{(n-k)×n}c^{T}=0;

(2) at a receiver, a received sequencey corresponding to the codeword c is received, and is demodulated and calculated to obtain a log-likelihood ratio sequence r ∈ [symbol] , then a hard decision sequence z ∈ [symbol] corresponding to the codeword is obtained according to r and then a representative OSD algorithm is executed; |rⱼ| is defined as reliability corresponding to zⱼ, e=(e_{L}, e_{R}) ∈ [symbol] is defined as a test error pattern, then v=z−e ∈ [symbol] is a test codeword; and a parameter δ,0≤δ≤n−k is set, and a specific process of decoding includes

(2.1) for the staircase generator matrix code, performing column permutation on the generator matrix based on reliability ranking of bits to obtain GΠ=[L_{k×k}|M_{k×δ}|N_{k×(n-k-δ)}], where L is an upper triangular or lower triangular matrix, corresponding to kreliable bits in k staircases, M_{k×δ} corresponds to & reliable bits of the remaining bits, and performing permutation corresponding to Π on r, z, v and e to obtain \tilde{r}, \tilde{z}, and \tilde{e}; and for the staircase parity-check matrix code, performing row and column permutation on the parity-check matrix based on the reliability ranking of bits to obtain

$${Π}_{L} H {Π}_{R} = [ \begin{matrix}{L}_{( n - k - δ ) \times ( n - k - δ )} & {M}_{( n - k - δ ) \times ( k + δ )} \\ {S}_{δ \times ( n - k - δ )} & {N}_{δ \times ( k + δ )}\end{matrix} ] ,$$

where L is an upper triangular or a lower triangular matrix, corresponding to n−k−δ unreliable bits in n−k staircases, and performing permutation corresponding to Π_{R} on r, z, v and e to obtain \tilde{r}, \tilde{z}, \tilde{v} and \tilde{e};

(2.2) for the staircase generator matrix code, executing conventional Gaussian elimination or parallel Gaussian elimination of all k rows on the basis of GΠ to obtain \tilde{G}=[I_{k×k}|P_{k×δ}|Q_{k×(n-k-δ)}], where I_{k×k} is a k-order unit matrix; and for the staircase parity-check matrix code, executing conventional Gaussian elimination processing or parallel Gaussian elimination processing of all n−k rows on the basis of Π_{L}HΠ_{R} to obtain

$$\tilde{H} = [ \begin{matrix}{I}_{( n - k - δ ) \times ( n - k - δ )} & {P}_{( n - k - δ ) \times ( k + δ )} \\ {O}_{δ \times ( n - k - δ )} & {Q}_{δ \times ( k + δ )}\end{matrix} ] ,$$

where I_{(n-k-δ)×(n-k-δ)} is an n−k−δ-order unit matrix, and O_{δ×(n-k-δ)} is an all-zero sub-matrix; and

(2.3) searching a test error pattern based on \tilde{G} or \tilde{H}, and executing re-encoding to obtain a candidate codeword list, and then selecting a candidate codeword having a most likelihood or satisfying a certain check as decoding outputs to complete decoding.

As a preferred technical solution, in step (1), profile distribution w=(w₀, w₁, . . . , wₖ₋₁) of the staircase generator matrix code or profile distribution w=(w₀, w₁, . . . , wₙ₋ₖ₋₁) of the staircase parity-check matrix code is arbitrary, including but not limited to uniform allocation, non-uniform allocation, special Reed-Muller code matrix structure-based allocation and polar code matrix structure-based allocation.

As a preferred technical solution, in step (1), a production way of the staircase code is arbitrary, including but not limited to a random way-based construction and a structured way-based construction.

As a preferred technical solution, in step (2), when δ=0, a decoding scheme includes but is not limited to various variant forms of original OSD and OSD; and when δ>0, a locally constrained OSD algorithm is employed.

As a preferred technical solution, in step (2.1), for the staircase generator matrix code, a form of a sub-matrix L is an arbitrary special triangular form, including but not limited to a form of an upper triangle, a lower triangle, a quasi-upper triangle or a quasi-lower triangle, and a way to obtain the sub-matrix L is arbitrary, and a typical implementation requires that column i of the permuted L corresponds to a most reliable bit in an i^{th} staircase of an original staircase generator matrix G, that is, the column i corresponds to a most reliable bit in zₜ(Σ_{0≤m<i}wₘ≤Σ_{0≤m<(i+1)}wₘ), and the δ columns of a sub-matrix M correspond to most reliable bits of the remaining n−k bits.

As a preferred technical solution, in step (2.1), for the staircase parity-check matrix code, a form of a sub-matrix L is an arbitrary triangular form, including but not limited to a form of an upper triangle, a lower triangle, a quasi-upper triangle or a quasi-lower triangle, and a way to obtain the sub-matrix L is arbitrary, and a typical implementation requires that n−k−δ columns of the permuted L correspond to n−k−δ least reliable bits in n−k staircases of an original staircase parity-check matrix H, and each staircase contributes at most one bit.

As a preferred technical solution, in step (2.2), the Gaussian elimination executed on a sub-matrix L included in the staircase generator matrix code or a sub-matrix U included in the staircase parity-check matrix code is implemented arbitrarily, including but not limited to conventional row-by-row serial Gaussian elimination, parallel Gaussian elimination of some of rows or parallel Gaussian elimination of all rows.

As a preferred technical solution, in step (2.3), an order of producing the candidate codewords is arbitrary, including but not limited to a Hamming weight-based reliable basis error pattern production order, a soft information-based reliable basis error pattern production order, or a local constraint-based reliable basis error pattern production order.

Compared with the prior art, the present disclosure has the following advantages and beneficial effects:

(1) according to the staircase matrix code and the highly parallel low-latency OSD method thereof proposed in the present disclosure, the performance of an approximation finite code length boundary can be obtained, and especially in a region with a medium-high signal-to-noise ratio, a lower number of re-encoding times can be obtained based on an optimized candidate codeword list sequence and early termination design, thereby implementing low-complexity, low-latency and high-reliability decoding.

(2) The present disclosure has an exquisite decoding design, and based on the special staircase generator matrix or staircase parity-check matrix, a permutation generator matrix or a permutation parity-check matrix has an upper triangular or a lower triangular structure in combination with special reliable basis selection, so that fully parallel Gaussian elimination can be implemented, and the latency required by the Gaussian elimination part is greatly reduced.

(3) The decoding of the present disclosure can be chosen from a variety of options, with the parameter δ 8 introduced therein, when δ=0, conventional OSD and variants thereof are employed, when δ>0, the locally constrained OSD is employed. The candidate codeword list can be optimized more effectively by the locally constrained OSD, and re-encoding times are reduced greatly in combination with the preferred early termination design.

(4) The encoding construction of the present disclosure is simple and easy to implement, and excellent performance can be obtained regardless of the random staircase code construction or the structured staircase code construction.

### BRIEF DESCRIPTION OF THE DRAWINGS

To describe the technical solutions of the embodiments of this application more clearly, a brief introduction will be given to the accompanying drawings required in the description of the embodiments. Obviously, the accompanying drawings in the following description show only some embodiments of this application, and a person of ordinary skill in the art may still obtain other drawings from these accompanying drawings without creative efforts.

FIG. 1 is a schematic diagram of a staircase matrix code and highly parallel low-latency OSD and coding/decoding transmission thereof according to the present disclosure;

FIG. 2 is an RM construction-based staircase generator matrix of n=8 according to the present disclosure;

FIG. 3 is an RM construction-based staircase parity-check matrix of n=8 according to the present disclosure;

FIG. 4 is a schematic diagram showing comparison of decoding performance in Embodiment 1 of the present disclosure;

FIG. 5 is a schematic graph showing comparison of re-encoding times in Embodiment 1 of the present disclosure;

FIG. 6 is a schematic diagram showing comparison of decoding performance in Embodiment 2 of the present disclosure;

FIG. 7 is a schematic graph showing comparison of re-encoding times in Embodiment 2 of the present disclosure;

FIG. 8 is a schematic diagram showing comparison of decoding performance in Embodiment 3 of the present disclosure; and

FIG. 9 is a schematic diagram of comparison of re-encoding times in Embodiment 3 of the present disclosure.

### DETAILED DESCRIPTION OF THE EMBODIMENTS

In order to enable those skilled in the art to better understand the solution of this application, the technical solution of the embodiments of this application will be clearly and completely described with reference to the accompanying drawings. Obviously, the described embodiments are merely some rather than all of the embodiments of this application. All other embodiments obtained by those skilled in the art based on the embodiments in the present application without making creative efforts fall within the scope of protection of this application.

Reference in this application to “embodiments” means that particular features, structures, or characteristics described in conjunction with the embodiment may be included in at least one embodiment of this application. The phrase appearing in various places in the specification does not necessarily refer to the same embodiment, nor is it an independent or alternative embodiment that is mutually exclusive with other embodiments. It is to be expressly and implicitly understood by those skilled in the art that the embodiments described in this application may be combined with other embodiments.

### Embodiment 1

A staircase matrix is described as: the [symbol] row of the staircase matrix is defined as [symbol] =( [symbol] , [symbol] , [symbol] ), where [symbol] is a binary sequence with a length of Σ_{0≤m<l}wₘₘₘ, [symbol] is an all-l sequence with a length of [symbol] ≥1, and [symbol] is an all-zero sequence with a length of n− [symbol] wₘ; the staircase matrix code is divided into a staircase generator matrix code and a staircase parity-check matrix code from a definition perspective, where a generator matrix of the staircase generator matrix code has a staircase structure or has a staircase structure after row and column permutation, k groups of w=(w₀, w₁, . . . , wₖ₋₁) constitute a profile of the staircase generator matrix, and wᵢ≥1, Σwᵢ=n; a parity-check matrix of the staircase parity-check matrix code has a staircase structure or has a staircase structure after row and column permutation, n−k groups of w=(w₀, w₁, . . . , wₙ₋ₖ₋₁) constitute a profile of the staircase parity-check matrix, and wᵢ≥1, Σwᵢ=n; and an information sequence u ∈ [symbol] and a staircase matrix code [symbol] [n, k] are given.

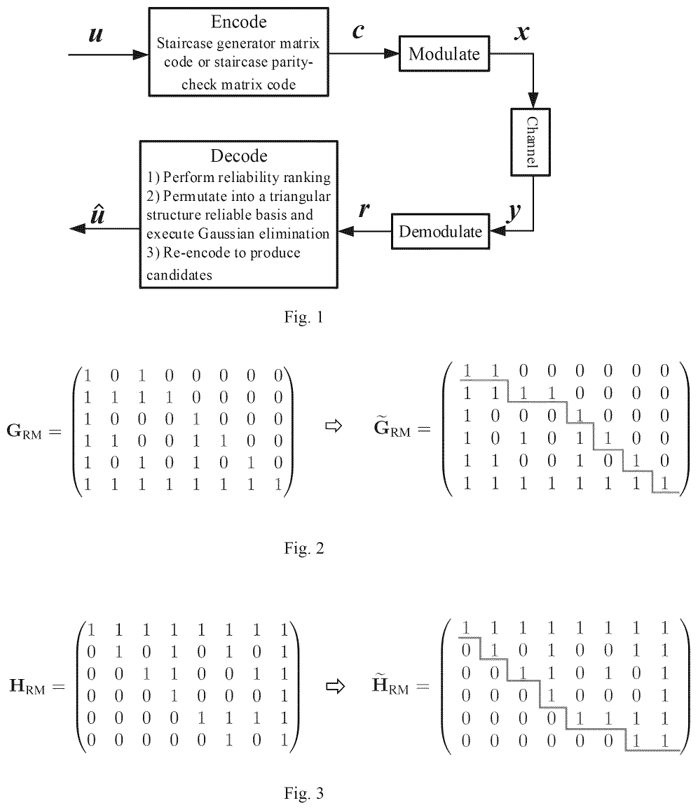

As shown in FIG. 1, this Embodiment 1 is a staircase matrix code and a highly parallel low-latency OSD method thereof, including the following steps:

At step (1), a codeword c of the staircase generator matrix code belongs to a row generator space of a staircase generator matrix G_{k×n}, namely, c ∈ {uG_{k×n}|u ∈ [symbol] }; and a codeword c of the staircase parity-check matrix code belongs to a null space of a staircase parity-check matrix H_{(n-k)×n}, namely, the codeword c satisfying H_{(n-k)×n}c^{T}=0.

Further, in step (1), profile distribution w=(w₀, w₁, . . . , wₖ₋) of the staircase generator matrix code or profile distribution w=(w₀, w₁, . . . , wₙ₋ₖ₋₁) of the staircase parity-check matrix code is arbitrary, including but not limited to uniform allocation, non-uniform allocation, special Reed-Muller code matrix structure-based allocation and polar code matrix structure-based allocation.

It should be noted that the production way of the staircase code in this embodiment is arbitrary, including but not limited to a random way-based construction, a structured way-based construction and the like. The production way of the staircase code in arbitrary way is applicable to this application. Construction process examples of a Reed-Muller code matrix structure-based staircase matrix code generator matrix and a Reed-Muller code matrix structure-based parity-check matrix are as shown in FIGS. 2 and 3, respectively.

At step (2), a receiver receives a received sequence y corresponding to the codeword c and demodulates and calculates the received sequence to obtain a log-likelihood ratio sequence r ∈ [symbol] , then a hard decision sequence z ∈ [symbol] corresponding to the codeword is obtained according to r, and then a representative OSD algorithm is executed; |rⱼ| is defined as reliability corresponding to zⱼ, and e=(e_{L}, e_{R}) ∈ [symbol] is defined as a test error pattern, then v=z−e ∈ [symbol] is a test codeword; and a parameter δ, 0≤δ≤n−k is set, and a specific process of decoding includes:

(2.1) for the staircase generator matrix code, performing column permutation on the generator matrix based on reliability ranking of bits to obtain GΠ=[L_{k×k}|M_{k×δ}|N_{k×(n-k-δ)}], where L is an upper triangular or lower triangular matrix, corresponding to kreliable bits in k staircases, M_{k×δ} corresponds to δreliable bits of the remaining bits, and performing permutation corresponding to Π on r, z, v and e to obtain \tilde{r}, \tilde{z}, \tilde{v} and \tilde{e}; and for the staircase parity-check matrix code, performing row and column permutation on the parity-check matrix based on the reliability ranking of bits to obtain

$${Π}_{L} H {Π}_{R} = [ \begin{matrix}{L}_{( n - k - δ ) \times ( n - k - δ )} & {M}_{( n - k - δ ) \times ( k + δ )} \\ {S}_{δ \times ( n - k - δ )} & {N}_{δ \times ( k + δ )}\end{matrix} ] ,$$

where L is an upper triangular or a lower triangular matrix, corresponding to n−k−δ unreliable bits in n−k staircases, and performing permutation corresponding to Π_{R} on r, z, v and e to obtain \tilde{r}, \tilde{z}, \tilde{v} and \tilde{e}.

Further, for the staircase generator matrix code, a form of a sub-matrix L is an arbitrary special triangular form, including but not limited to a form of an upper triangle, a lower triangle, a quasi-upper triangle or a quasi-lower triangle, and a way to obtain the sub-matrix L is arbitrary, and a typical implementation requires that column i of the permuted L corresponds to a most reliable bit in an i^{th} staircase of an original staircase generator matrix G, that is, the column icorresponds to a most reliable bit in zₜ(Σ_{0≤m<i}wₘ≤t<Σ_{0≤m<(i+1)}wₘ), and the δcolumns of a sub-matrix M correspond to most reliable bits of the remaining n−k bits.

Further, for the staircase parity-check matrix code, a form of a sub-matrix L is an arbitrary triangular form, including but not limited to a form of an upper triangle, a lower triangle, a quasi-upper triangle or a quasi-lower triangle, and a way to obtain the sub-matrix L is arbitrary, and a typical implementation requires that n−k−δ columns of the permuted L correspond to n−k−δ least reliable bits in n−k staircases of an original staircase parity-check matrix H, and each staircase contributes at most one bit.

(2.2) for the staircase generator matrix code, executing conventional Gaussian elimination or parallel Gaussian elimination of all k rows on the basis of GΠ to obtain \tilde{G}=[I_{k×k}|P_{k×δ}|Q_{k×(n-k-δ)}], where I_{k×k} is a k-order unit matrix; and for the staircase parity-check matrix code, executing conventional Gaussian elimination processing or parallel Gaussian elimination processing of all n−krows on the basis of Π_{L}HΠ_{R} to obtain

$$\tilde{H} = [ \begin{matrix}{I}_{( n - k - δ ) \times ( n - k - δ )} & {P}_{( n - k - δ ) \times ( k + δ )} \\ {O}_{δ \times ( n - k - δ )} & {Q}_{δ \times ( k + δ )}\end{matrix} ] ,$$

where I_{(n-k-δ)×(n-k-δ)} is an n−k−δ—order unit matrix, and O_{δ×(n-k-δ)} is an all-zero sub-matrix.

Further, the Gaussian elimination executed on a sub-matrix L included in the staircase generator matrix code or a sub-matrix Uincluded in the staircase parity-check matrix code is implemented arbitrarily, including but not limited to conventional row-by-row serial Gaussian elimination, parallel Gaussian elimination of some of rows or parallel Gaussian elimination of all rows.

(2.3) searching a test error pattern based on \tilde{G} or \tilde{H}, and executing re-encoding to obtain a candidate codeword list, and then selecting a candidate codeword having a most likelihood or satisfying a certain check as decoding outputs to complete decoding.

Further, an order of producing the candidate codewords is arbitrary, including but not limited to a Hamming weight-based reliable basis error pattern production order, a soft information-based reliable basis error pattern production order, or a local constraint-based reliable basis error pattern production order.

Furthermore, the decoding method of the present embodiment is diversified, with the parameter δ introduced therein, when δ=0, conventional OSD and variants thereof are employed, when δ>0, the locally constrained OSD is employed.

### Embodiment 2

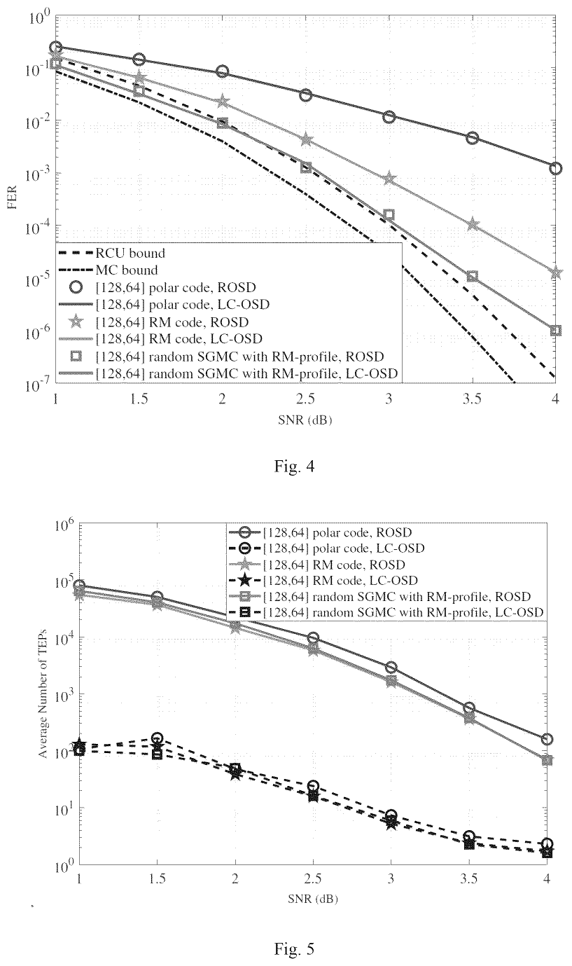

This embodiment 2 is used for a staircase matrix code and a highly parallel low-latency OSD algorithm thereof. A Reed-Muller (RM) code, a polar code, and an RM profile-based random staircase generator matrix code (SGMC) each with parameters [128,64] are considered. An information bit sequence u with a length of 64 is correspondingly encoded to obtain a codeword c, and then c is binary phase-shift keying (BPSK) modulated and transmitted over an additive white Gaussian noise (AWGN) channel. A receiver restores a sending sequence by employing representative OSD (ROSD) of parameters [symbol] =10⁶ and δ=12. As a comparison object, this example also gives the performance of employing locally constrained OSD (LC-OSD) for three codes. Comparison in the frame error rate (FER) is as shown in FIG. 4. It can be seen that the performance of the random generator matrix code proposed in the present disclosure is superior to that of the polar code and the RM-based random generator matrix code, and obtains the performance of an approximation finite code length boundary. Moreover, an ROSD algorithm of the random generator matrix code proposed in the present disclosure has a similar FER to an LC-OSD algorithm. Comparison of average number of tests is as shown in FIG. 5. The ROSD algorithm proposed in the present disclosure has a slightly higher average number of tests than the LC-OSD, but the average number of tests of the ROSD algorithm can be reduced to less than 100 times in a very low FER region that may be more concerned in a future 6G high-reliability and low-latency scenario.

### Embodiment 3

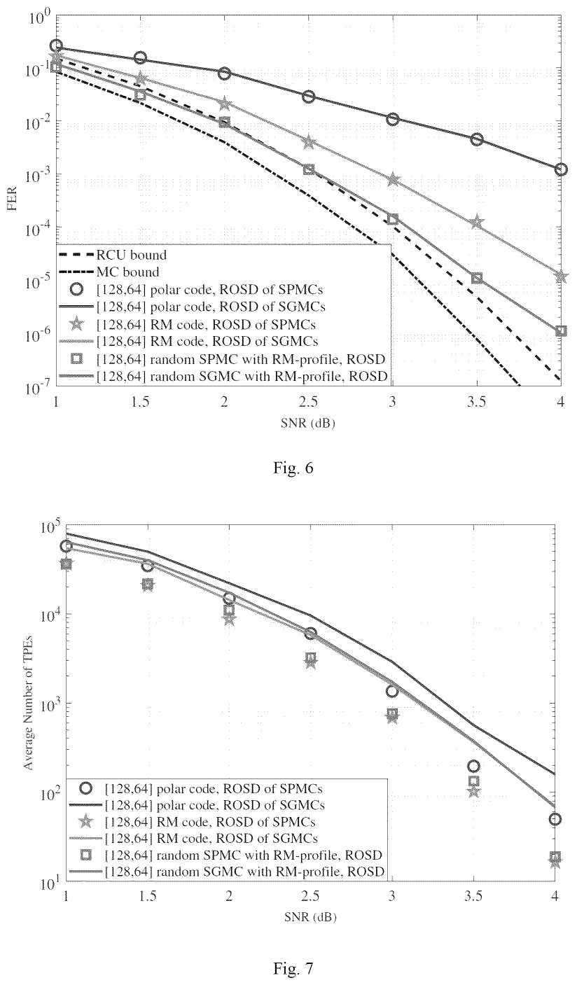

This embodiment 3 is used for a staircase matrix code and a highly parallel low-latency OSD algorithm thereof. An RM code, a polar code and an RM profile-based random staircase matrix code (SMC) each with parameters [128,64] are considered. An information bit sequence u with a length of 64 is correspondingly encoded to obtain a codeword c, and then cis BPSK modulated and transmitted over an AWGN channel. A receiver restores a sending sequence by employing ROSD of parameters [symbol] =10⁶ and δ=12. As a comparison object, this example also gives the performance of executing ROSD decoding on the RM code and the polar codes from a perspective of a generator matrix and a parity-check matrix. Comparison in FER is as shown in FIG. 6. It can be seen that a staircase generator matrix code and a staircase parity-check matrix code have a similar FER under ROSD decoding, and are significantly superior to the RM code and the polar code. Comparison of average number of tests is as shown in FIG. 7. It can be seen that the staircase parity-check matrix code proposed in the present disclosure has a lower average number of tests than the staircase generator matrix code, and the average number of tests of the ROSD algorithm can be reduced to less than 100 times in a very low FER region that may be more concerned in a future 6G high-reliability and low-latency scenario.

### Embodiment 4

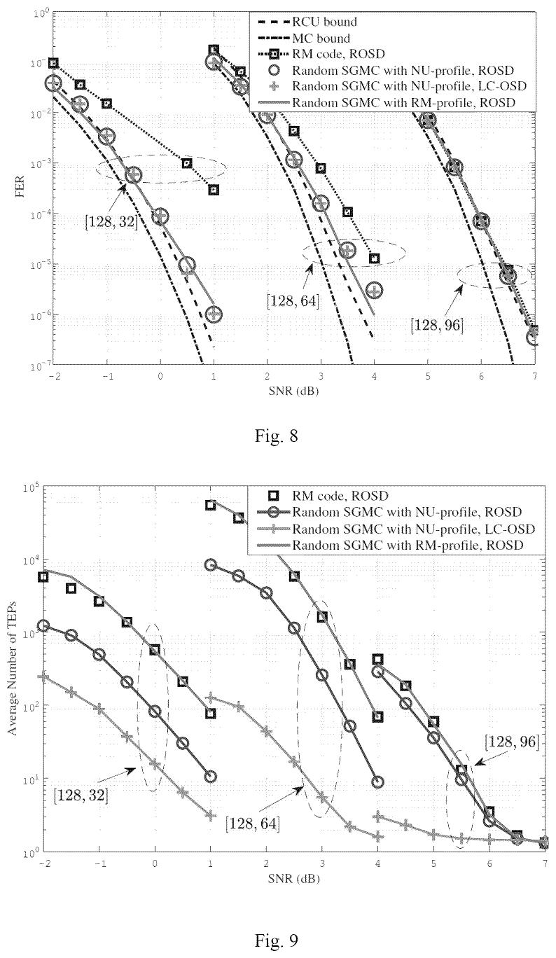

This embodiment 4 is used for a staircase matrix code and a highly parallel low-latency OSD algorithm thereof. SMC with RM-profile or NU-profile with code parameters [128,96], [128,64] and [128,32] are considered. An information bit sequenceu is correspondingly encoded to obtain a codeword c, and then c is BPSK modulated and transmitted over an AWGN channel. A receiver restores a sending sequence by employing ROSD or LC-OSC of parameters [symbol] =10⁶ and δ=12. As a comparison object, this example also gives the performance of executing ROSD decoding on an RM code with code parameters [128,96], [128,64] and [128,32]. Comparison in FER is as shown in FIG. 8. It can be seen that the staircase matrix code employing an RM profile and a near random profile has similar FER, and the proposed ROSD algorithm has a similar FER to a high-performance LC-OSD algorithm. Moreover, the performance of the proposed staircase code is significantly superior to that of the RM code in a medium-low-code-rate region. Comparison of average number of tests is as shown in FIG. 9. It can be seen that the near random profile further proposed in the present disclosure has a lower average number of tests than the RM profile, and the average number of tests, under the ROSD algorithm, of the SMC with the near random profile can be reduced to less than ten times in a very low FER region that may be more concerned in a future 6G high-reliability and low-latency scenario.

It should be noted that for each of the aforementioned method embodiments, for the sake of simplicity, the method embodiments are described as a series of action combinations, but those of ordinary skill in the art learn that the present disclosure is not limited to an order of described actions, because according to the present disclosure, some steps may be performed in another order or at the same time.

Those of ordinary skill in the art should understand that all or part of the flows of the method in the foregoing embodiment can be implemented by a computer program instructing relevant hardware. The program can be stored in a non-volatile computer readable storage medium. The program, when executed, may include, for example, the flows of the embodiment of the above-mentioned method. Any references to a memory, storage, a database, or other media used in each embodiment provided in this application may all include a non-volatile memory or a volatile memory. The non-volatile memory may include a read-only memory (ROM), a programmable ROM (PROM), an electrically programmable ROM (EPROM), an electrically erasable programmable ROM (EEPROM), or a flash memory. The volatile memory may include a random access memory (RAM) or an external cache memory. As an illustration rather than a limitation, RAM is available in various forms such as static RAM (SRAM), dynamic RAM (DRAM), synchronous DRAM (SDRAM), double data rate SDRAM (DDRSDRAM), enhanced SDRAM (ESDRAM), synchlink DRAM (SLDRAM), Rambus direct RAM (RDRAM), direct Rambus dynamic RAM (DRDRAM), and Rambus dynamic RAM (RDRAM) and the like.

The various technical features of the above embodiments can be combined arbitrarily. In order to make the description concise, all possible combinations of the technical features in the above embodiments are not described. However, as long as there is no contradiction in the combination of these technical features, they should be considered to be within the scope of this description.

The above-mentioned embodiments are preferred implementations of the present disclosure, but the implementations of the present disclosure are not limited to the above-mentioned embodiments, and any other changes, modifications, substitutions, combinations and simplifications made without departing from the spirit and principles of the present disclosure are to be construed as equivalent substitutions and are all included within the protection scope of the present disclosure.

1. A staircase matrix code and a highly parallel low-latency ordered statistics decoding (OSD) method thereof, wherein a staircase matrix is described as: the [symbol] row of the staircase matrix is defined as [symbol] =( [symbol] , [symbol] , [symbol] ), wherein [symbol] is a binary sequence with a length of 93 _{0≤m<l}wₘ, [symbol] is an all-l sequence with a length of [symbol] ≥1, and [symbol] is an all-zero sequence with a length of n− [symbol] wₘ; the staircase matrix code is divided into a staircase generator matrix code and a staircase parity-check matrix code from a definition perspective, wherein a generator matrix of the staircase generator matrix code has a staircase structure or has a staircase structure after row and column permutation, k groups of w=(w₀, w₁, . . . , wₖ₋₁) constitute a profile of the staircase generator matrix, and wᵢ≥1, Σwᵢ=n; a parity-check matrix of the staircase parity-check matrix code has a staircase structure or has a staircase structure after row and column permutation, n−k groups of w=(w₀, w₁, . . . , wₙ₋ₖ₋₁) constitute a profile of the staircase parity-check matrix, and wᵢ≥1, Σwᵢ=n; and an information sequence u ∈ [symbol] and a staircase matrix code [symbol] [n, k] are given, a specific coding and decoding process of the staircase matrix code and the highly parallel low-latency OSD method thereof comprising:
(1) a codeword c of the staircase generator matrix code is in a row generator space of a staircase generator matrix G_{k×n}, namely, c ∈ {uG_{k×n}|u ∈ [symbol] }; and a codeword c of the staircase parity-check matrix code is in a null space of a staircase parity-check matrix H_{(n-k)×n}, namely, the codeword c satisfying H_{(n-k)×n}c^{T}=0;
(2) at a receiver, a received sequence y corresponding to the codeword c is received, and is demodulated and calculated to obtain a log-likelihood ratio sequence r ∈ [symbol] , then a hard decision sequence z ∈ [symbol] corresponding to the codeword is obtained according to r, and then a representative OSD algorithm is executed; |rⱼ| is defined as reliability corresponding to zⱼ, e=(e_{L}, e_{R}) ∈ [symbol] is defined as a test error pattern, then v=z−e ∈ [symbol] is a test codeword; and a parameter δ, 0≤δ≤n−k is set, and a specific process of decoding comprises:
(2.1) for the staircase generator matrix code, performing column permutation on the generator matrix based on reliability ranking of bits to obtain GΠ=[L_{k×k}|M_{k×δ}|N_{k×(n-k-δ)}], wherein L is an upper triangular or lower triangular matrix, corresponding to k reliable bits in k staircases, M_{k×δ} corresponds to δ reliable bits of the remaining bits, and performing permutation corresponding to Π on r, z, v and e to obtain \tilde{r}, \tilde{z}, \tilde{v} and \tilde{e}; and for the staircase parity-check matrix code, performing row and column permutation on the parity-check matrix based on the reliability ranking of bits to obtain
$${Π}_{L} H {Π}_{R} = [ \begin{matrix}{L}_{( n - k - δ ) \times ( n - k - δ )} & {M}_{( n - k - δ ) \times ( k + δ )} \\ {S}_{δ \times ( n - k - δ )} & {N}_{δ \times ( k + δ )}\end{matrix} ] ,$$
wherein L is an upper triangular or a lower triangular matrix, corresponding to n−k−δ unreliable bits in n−k staircases, and performing permutation corresponding to Π_{R} on r, z, v and e to obtain \tilde{r}, \tilde{z}, and \tilde{e};
(2.2) for the staircase generator matrix code, executing conventional Gaussian elimination or parallel Gaussian elimination of all k rows on the basis of GΠ to obtain \tilde{G}=[I_{k×k}|P_{k×δ}|Q_{k×(n-k-δ)}], wherein I_{k×k} is a k-order unit matrix; and for the staircase parity-check matrix code, executing conventional Gaussian elimination processing or parallel Gaussian elimination processing of all n−k rows on the basis of Π_{L}HΠ_{R} to obtain
$$\tilde{H} = [ \begin{matrix}{I}_{( n - k - δ ) \times ( n - k - δ )} & {P}_{( n - k - δ ) \times ( k + δ )} \\ {O}_{δ \times ( n - k - δ )} & {Q}_{δ \times ( k + δ )}\end{matrix} ] ,$$
wherein I_{(n-k-δ)×(n-k-δ)} is an n−k−δ—order unit matrix, and O_{δ×(n-k-δ)} is an all-zero sub-matrix; and
(2.3) searching a test error pattern based on \tilde{G} or \tilde{H}, and executing re-encoding to obtain a candidate codeword list, and then selecting a candidate codeword having a most likelihood or satisfying a certain check as decoding outputs to complete decoding.

2. The staircase matrix code and the highly parallel low-latency OSD method thereof according to claim 1, wherein in step (1), profile distribution w=(w₀, w₁, . . . , wₖ₋₁) of the staircase generator matrix code or profile distribution w=(w₀, w₁, . . . , wₙ₋ₖ₋₁) of the staircase parity-check matrix code is arbitrary, comprising but not limited to uniform allocation, non-uniform allocation, special Reed-Muller code matrix structure-based allocation and polar code matrix structure-based allocation.

3. The staircase matrix code and the highly parallel low-latency OSD method thereof according to claim 1, wherein in step (1), a production way of the staircase code is arbitrary, comprising but not limited to a random way-based construction and a structured way-based construction.

4. The staircase matrix code and the highly parallel low-latency OSD method thereof according to claim 1, wherein in step (2), when δ=0, a decoding scheme comprises but is not limited to various variant forms of original OSD and OSD; and when δ>0, a local constraint-based OSD algorithm is employed.

5. The staircase matrix code and the highly parallel low-latency OSD method thereof according to claim 1, wherein in step (2.1), for the staircase generator matrix code, a form of a sub-matrix L is an arbitrary special triangular form, comprising but not limited to a form of an upper triangle, a lower triangle, a quasi-upper triangle or a quasi-lower triangle, and a way to obtain the sub-matrix L is arbitrary, and a typical implementation requires that column i of the permuted L corresponds to a most reliable bit in an i^{th} staircase of an original staircase generator matrix G, that is, the column i corresponds to a most reliable bit in zₜ(Σ_{0≤m<i}wₘ≤t<Σ_{0≤m<(i+1)}wₘ), and the δ columns of a sub-matrix M correspond to most reliable bits of the remaining n−kbits.

6. The staircase matrix code and the highly parallel low-latency OSD method thereof according to claim 1, wherein in step (2.1), for the staircase parity-check matrix code, a form of a sub-matrix L is an arbitrary triangular form, comprising but not limited to a form of an upper triangle, a lower triangle, a quasi-upper triangle or a quasi-lower triangle, and a way to obtain the sub-matrix L is arbitrary, and a typical implementation requires that n−k−δ columns of the permuted L correspond to n−k−δ least reliable bits in n−k staircases of an original staircase parity-check matrix H, and each staircase contributes at most one bit.

7. The staircase matrix code and the highly parallel low-latency OSD method thereof according to claim 1, wherein in step (2.2), the Gaussian elimination executed on a sub-matrix Lcomprised in the staircase generator matrix code or a sub-matrix U comprised in the staircase parity-check matrix code is implemented arbitrarily, comprising but not limited to conventional row-by-row serial Gaussian elimination, parallel Gaussian elimination of some of rows or parallel Gaussian elimination of all rows.

8. The staircase matrix code and the highly parallel low-latency OSD method thereof according to claim 1, wherein in step (2.3), an order of producing the candidate codewords is arbitrary, comprising but not limited to a Hamming weight-based reliable basis error pattern production order, a soft information-based reliable basis error pattern production order, or a local constraint-based reliable basis error pattern production order.
